(19) United States
(12) Patent Application Publication
(10) Pub. No.: US 2022/0052037 A1
(43) Pub. Date: Feb. 17, 2022

(54) ELECTROSTATIC DISCHARGE CIRCUIT

(71) Applicant: UNITED MICROELECTRONICS CORP., Hsinchu (TW)

(72) Inventors: Teng-Chuan CHEN, Hsinchu City (TW); Chun CHIANG, Hsinchu City (TW); Tien-Hao TANG, Hsinchu City (TW)

(21) Appl. No.: 16/989,942

(22) Filed: Aug. 11, 2020

(51) Int. Cl. H01L 27/02; H02H 9/04

(52) U.S. Cl. CPC H01L 27/0285; H01L 27/0274; H02H 9/046

(57) ABSTRACT

An electrostatic discharge circuit is provided. The electrostatic discharge circuit includes a cascade transistor configuration and a control circuit. The cascade transistor configuration includes a first transistor and a second transistor coupled between a power supply node and a ground node. The control circuit is coupled to the cascade transistor configuration, and coupled between the power supply node and the ground node. The control circuit includes a voltage drop circuit coupled to the power supply node and the first transistor, and an electrostatic discharge detecting circuit between the voltage drop circuit and the ground node. The electrostatic discharge detecting circuit is coupled to the first transistor and the second transistor.

### BACKGROUND

### Technical Field

The disclosure relates to an electrostatic discharge circuit, and more particularly to an electrostatic discharge circuit with a control circuit.

### Description of the Related Art

Electrostatic discharge (ESD) may cause damage to sensitive electronic devices, especially nano-scale electronic components. Even low levels of electrostatic discharge may have a serious impact on sensitive electronic devices and result in immediate and permanent damage to electronic devices. In order to minimize electrostatic discharge, electrostatic discharge circuits are typically provided in semiconductor devices to control charge leakage paths.

A N-type metal-oxide-semiconductor (NMOS) transistor structure may be applied in an electrostatic discharge circuit. However, there are still challenges pertinent to the design of NMOS type electrostatic discharge circuits; for example, with the scaling of the semiconductor devices, the trigger voltages of the NMOS type electrostatic discharge circuits are too high to reliably protect the semiconductor devices.

An electrostatic discharge circuit having a lower trigger voltage may be beneficial to manufacturing cost, yield, reliability, and so on.

### SUMMARY

The present disclosure relates to an electrostatic discharge circuit.

According to an embodiment of the present disclosure, an electrostatic discharge circuit is provided. The electrostatic discharge circuit includes a cascade transistor configuration and a control circuit coupled to the cascade transistor configuration. The cascade transistor configuration includes a first transistor and a second transistor coupled between a power supply node and a ground node. The control circuit is coupled between the power supply node and the ground node. The control circuit includes a voltage drop circuit and an electrostatic discharge detecting circuit. The voltage drop circuit is coupled to the power supply node and the first transistor. The electrostatic discharge detecting circuit is between the voltage drop circuit and the ground node, and coupled to the first transistor and the second transistor.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a schematic electrostatic discharge circuit according to an embodiment of the present disclosure.

FIG. 2 illustrates a schematic electrostatic discharge circuit according to an embodiment of the present disclosure.

FIG. 3 illustrates test results according to an embodiment of the present disclosure.

### DETAILED DESCRIPTION

Various embodiments will be described more fully hereinafter with reference to accompanying drawings, which are provided for illustrative and explaining purposes rather than a limiting purpose. For clarity, the components may not be drawn to scale. In addition, some components and/or reference numerals may be omitted from some drawings. It is contemplated that the elements and features of one embodiment can be beneficially incorporated in another embodiment without further recitation.

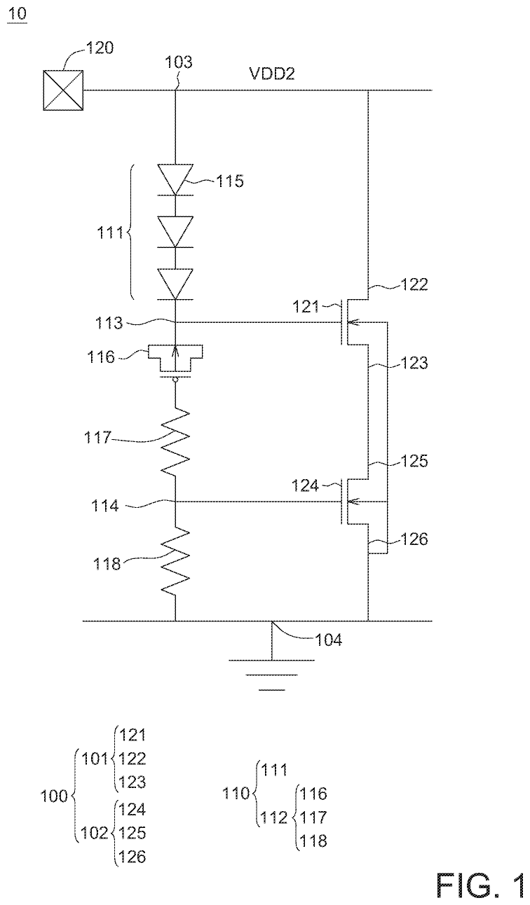

FIG. 1 illustrates a schematic electrostatic discharge circuit 10 according to an embodiment of the present disclosure. Referring to FIG. 1, the electrostatic discharge circuit 10 includes a cascade transistor configuration 100 and a control circuit 110. The cascade transistor configuration 100 is coupled to the control circuit 110 and coupled between a power supply node 103 and a ground node 104. The control circuit 110 is coupled to the cascade transistor configuration 100 and between the power supply node 103 and the ground node 104. In an embodiment, the control circuit 110 and the cascade transistor configuration 100 are arranged in parallel.

The cascade transistor configuration 100 includes a first transistor 101 and a second transistor 102. The first transistor 101 is coupled to the power supply node 103, the second transistor 102 and the control circuit 110. The second transistor 102 is coupled to the first transistor 10, the ground node 104 and the control circuit 110. In an embodiment, the first transistor 101 and the second transistor 102 may be arranged in series. The control circuit 110 includes a voltage drop circuit 111 and an electrostatic discharge detecting circuit 112. The voltage drop circuit 111 is coupled to the power supply node 103, the first transistor 101 and the electrostatic discharge detecting circuit 112. The electrostatic discharge detecting circuit 112 is coupled to the voltage drop circuit 111, the first transistor 101, the second transistor 102 and the ground node 104. The electrostatic discharge detecting circuit 112 is between the voltage drop circuit 111 and the ground node 104.

In an embodiment, a first node 113 may be provided between the voltage drop circuit 111 and the electrostatic discharge detecting circuit 112. The voltage drop circuit 111 is coupled between the power supply node 103 and the first node 113. The voltage drop circuit 111 includes at least one diode 115 coupled between the power supply node 103 and the first node 113. In an embodiment, the voltage drop circuit 111 may include a plurality of diodes 115 arranged in series.

The electrostatic discharge detecting circuit 112 includes a capacitor 116, a first resistor 117, and a second resistor 118 coupled between the first node 113 and the ground node 104. In an embodiment, the capacitor 116, the first resistor 117 and the second resistor 118 may be arranged in series. In an embodiment, a second node 114 may be provided between the first resistor 117 and the second resistor 118. The capacitor 116 and the first resistor 117 is coupled between the first node 113 and the second node 114. The second resistor 118 is coupled between the second node 114 and the ground node 104. When a voltage is applied to the control circuit 110, the first resistor 117 and the second resistor 118 generate a divided voltage at the second node 114.

The first transistor 101 includes a first gate 121, a first drain 122 and a first source 123. The second transistor 102 includes a second gate 124, a second drain 125 and a second source 126. In an embodiment, the first drain 122 may be coupled to the power supply node 103, the first gate 121 is coupled to the first node 113, and the first source 123 is coupled to the second drain 125; the second gate 124 is coupled to the second node 114, and the second source 126 is coupled to the ground node 104. Specifically, the voltage drop circuit 111 is coupled to the first gate 121 of the first transistor 101 with the first node 113.

In an embodiment, the first transistor 101 and/or the second transistor 102 may be a N-type metal-oxide-semiconductor (NMOS) transistor. In an embodiment, the first transistor 101 and the second transistor 102 may all be NMOS transistors.

In an embodiment, the power supply node 103 may be coupled to an input and output (I/O) pad 120, the I/O pad 120 may receive power supply from an external power source (not shown). A ground voltage may be applied at the ground node 104. The ground voltage may be understood as Vss. The ground node 104 may be at a voltage less than the voltage at the first node 113 and the voltage at the second node 114. For example, the ground node 104 is at 0V.

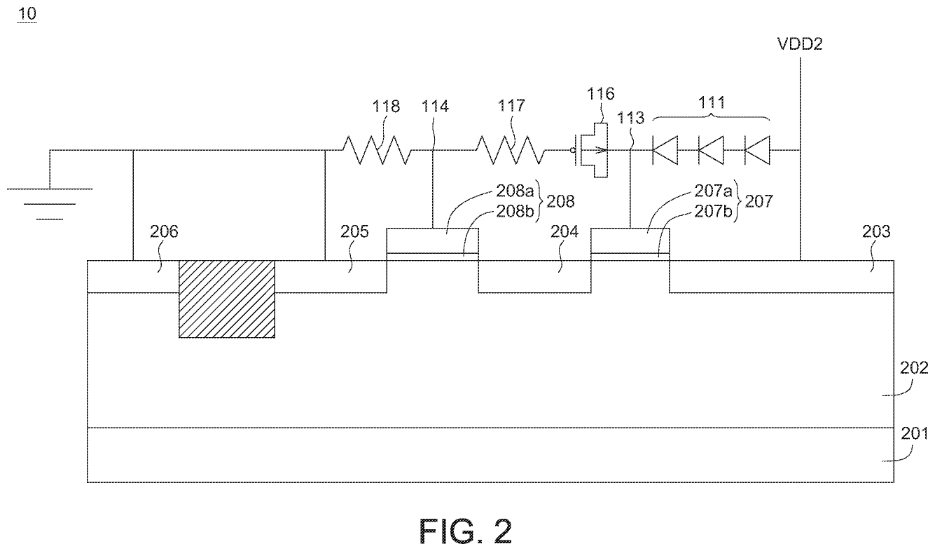

FIG. 2 illustrates a schematic electrostatic discharge circuit 10 according to an embodiment of the present disclosure. In FIG. 2, a structure of the cascade transistor configuration 100 is exemplarily provided. Referring to FIG. 2, the cascade transistor configuration 100 may include a substrate 201, a well region 202 formed on the substrate 201, a first doping region 203, a second doping region 204, a third doping region 205, a fourth doping region 206, a first gate structure 207 and a second gate structure 208.

In some embodiments of the present disclosure, the substrate 201 can be a semiconductor substrate, such as a silicon wafer. In one embodiment, the substrate 201 is a bulk semiconductor substrate made of single-crystal silicon or poly-silicon. However, in some other embodiments, the substrate 201 can further include other layer, such as semiconductor layers consisting of semiconductor material other than silicon or insulating layers (not shown). In the present embodiment, the substrate 201 can be a silicon wafer, the well region 202 can a silicon layer having a first conductivity formed by a deposition process, such as a low pressure chemical vapor deposition (LPCVD) process, performed on the surface of the semiconductor substrate 201.

In the present embodiment, the first doping region 203, the second doping region 204, the third doping region 205 and the fourth doping region 206 may be formed by at least one ion implantation performed on the surface of the semiconductor substrate 201. The first doping region 203, the second doping region 204, the third doping region 205 and the fourth doping region 206 are disposed in the well region 202 separately.

The first gate structure 207 including a gate electrode 207a and a gate dielectric layer 207b is disposed on the well region 202 and between the first doping region 203 and the second doping region 204. The second gate structure 208 including a gate electrode 208a and a gate dielectric layer 208b is disposed on the well region 202 and between the second doping region 204 and the third doping region 205. The first doping region 203, the second doping region 204 and the first gate structure 207 are combined to form the first transistor 101; the second doping region 204, the third doping region 205, and the second gate structure 208 are combined to form the second transistor 102. The first gate structure 207 may serve as the first gate 121 of the first transistor 101, and the second gate structure 208 may serve as the second gate 124 of the second transistor 102. The first doping region 203 serves as the first drain 122 of the first transistor 101; the second doping region 204 serve as the first source 123 of the first transistor 101 and the second drain 125 of the second transistor 102; the third doping region 205 serves as the second source 126 of the second transistor 102.

The substrate 201 may have a first conductivity type. The well region 202 may have a first conductivity type. The first doping region 203, the second doping region 204 and the third doping region 205 may have a second conductivity type with high impurity concentrations. The fourth doping region 206 may have a first conductivity type with a high impurity concentration. The first conductivity type is opposite to the second conductivity type. In an embodiment, the first conductivity type may be P-type, the second conductivity type may be N-type, the first doping region 203, the second doping region 204 and the third doping region 205 may be considered as N+ regions, and the fourth doping region 206 may be considered as a P+ region.

The well region 202 may be functioned as the body regions of the first transistor 101 and the second transistor 102. As shown in FIG. 2, the body regions of the first transistor 101 and second transistor 102 are all coupled to the ground node 104. In an embodiment, the first doping region 203, the well region 202 and the third doping region 205 may be functioned as a parasitic bipolar junction transistor (BJT).

As shown in FIGS. 1-2, when an ESD event occurs, an ESD pulse flows through the power supply node 103 to the voltage drop circuit 111, the voltage drop circuit 111 receives the ESD pulse to generate a first control voltage to turn on the first transistor 101, and the electrostatic discharge detecting circuit 112 generate a second control voltage to turn on the second transistor 102 through the second node 114. Current flows through a first channel provided between the first doping region 203 and the second doping region 204 and a second channel provided between the second doping region 204 and the third doping region 205. The current flowing through the first channel and the second channel allows the parasitic bipolar junction transistor to be turned on more rapidly, which means a high turn-on speed of the electrostatic discharge circuit can be achieved.

The voltage drop circuit 111 drops a voltage inputted into the voltage drop circuit 111. The voltage received at the first node 113 is lower than the voltage received at the power supply node 103. In an embodiment, a dropped voltage in response to a voltage dropped by the voltage drop circuit 111 is less than the breakdown voltage of the first transistor 101. In an embodiment, each diode 115 of the voltage drop circuit 111 may have a voltage drop of 0.7V to the voltage inputted into the voltage drop circuit 111. For example, a difference in voltage between the voltage received at the first node 113 and the voltage received at the power supply node 103 may be 2.1V as the voltage drop circuit 111 includes three diodes. The voltage drop circuit 111 may reduce the voltage applied to the first gate 121 of the first transistor 101 of the cascade transistor configuration 100 so as to protect the first transistor 101 from being damaged when the ESD event does not occur (i.e. during a normal operation). Providing the voltage drop circuit 111 in the electrostatic discharge circuit 10 is beneficial to protect the first transistor 101 from the reliability issue, and a high turn-on speed of the electrostatic discharge circuit can be thus achieved. In addition, during the normal operation, the first transistor 101 is turned on since the voltage applied to the first gate 121 of the first transistor 101 is higher than a threshold voltage of first transistor 101, and the second transistor 102 is still turned off so as to prevent huge leakage current between the power supply node 103 and the ground node 104.

The first resistor 117 has a first electrical resistance, and the second resistor 118 has a second electrical resistance. In an embodiment, the first electrical resistance of the first resistor 117 and the second electrical resistance of the second resistor 118 may be all larger than 5 Kohm (KΩ). In an embodiment, a ratio of the first electrical resistance of the first resistor 117 to the second electrical resistance of the second resistor 118 ranges substantially from 1 to 2. The first electrical resistance of the first resistor 117 is larger than the second electrical resistance of the second resistor 118 thereby enhancing a gate couple voltage on the first gate 121 of the first transistor 101 during the ESD event and reducing leakage current in the second channel during a normal operation. The enhanced gate couple voltage is beneficial to solve a non-uniform current distribution problem of the electrostatic discharge circuit 10, which may reduce the ESD protection performance.

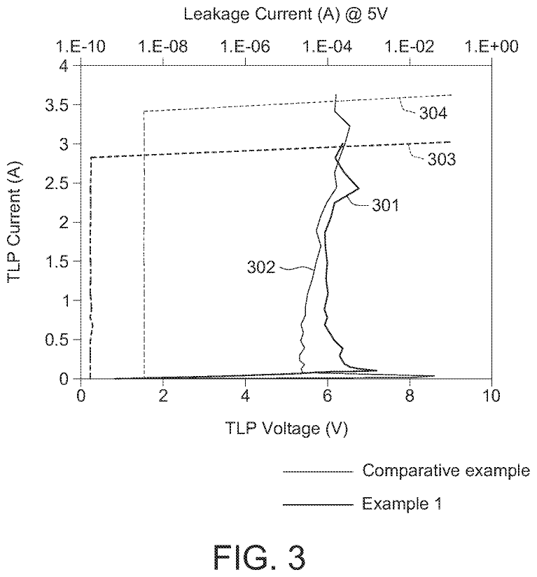

The electrostatic discharge circuit 10 provided by the present disclosure (referred to as the example 1) and a traditional cascade NMOS electrostatic discharge circuit (referred to as the comparative example) are then subjected to a transmission line pulse (TLP) test is performed. The trigger voltage (Vt1), holding voltage (Vh), second breakdown current (It2) and leakage current obtained by the TLP test are listed in Table 1. FIG. 3 illustrates test results of the TLP test, wherein curves 301 and 302 respectively represent the TLP-measured current-voltage (I-V) curves of the example 1 and the comparative example, and curves 303 and 304 respectively represent the corresponding current leakage of the example 1 and the comparative example. Under the test condition of FIG. 3, the second power-supply voltage (VDD2) is 5V, the voltage at the first node 113 is 2.9V, the voltage between the first transistor 101 and the second transistor 102 is 2.2V and a voltage at the second node 114 is 0V.

According to the results of the TLP test (with reference to Table 1 and FIG. 3), the Vt1 of the example 1 according to the present disclosure is lower than the Vt1 of the comparative example 1, which means the electrostatic discharge circuit 10 provided by the present disclosure (the example 1) can be turn on earlier than the traditional cascade NMOS electrostatic discharge circuit (the comparative example 1) while an ESD event occurs, and a high turn-on speed can be achieved. Specifically, the Vt1 of the example 1 according to the present disclosure is decreased by about 16% as compared with the Vt1 of the comparative example.

In addition, the Vh of the example 1 according to the present disclosure is higher than the Vh of the comparative example, which may prevent the electrostatic discharge circuit 10 from being undesirably turned on by noise pulses and also prevent a latchup issue during normal operation. The leakage current of the example 1 according to the present disclosure is lower than the leakage current of the comparative example, which means a problem of power loss resulting from the leakage current can be improved by using the electrostatic discharge circuit 10 of the present disclosure (the example 1. Specifically, the leakage current of the example 1 according to the present disclosure is decreased by about 95% as compared with the leakage current of the comparative example.

TABLE 1

| | | | | leakage current |
|---|---|---|---|---|
| | Vt1 (V) | Vh (V) | It2 (A) | (A) |
| comparative | 8.6 | 5.3 | 3.4 | 3.6E−9 |
| example | | | | |
| example 1 | 7.2 | 5.9 | 2.8 | 1.8E−10 |

According to the aforementioned descriptions, a control circuit is provided in the electrostatic discharge circuit, wherein the control circuit can reduce the trigger voltage of the cascade transistor configuration, allow the parasitic bipolar junction transistor to be turned on more rapidly and reduce the leakage current. Therefore, the electrostatic discharge circuit according to the present disclosure is provided with a high turn-on speed, a low power loss and an improved latchup issue, thereby significantly improving the ESD protection performance, manufacturing cost, yield and reliability of the electrostatic discharge circuit.

It is noted that the structures and methods as described above are provided for illustration. The disclosure is not limited to the configurations and procedures disclosed above. Other embodiments with different configurations of known elements can be applicable, and the exemplified structures could be adjusted and changed based on the actual needs of the practical applications. It is, of course, noted that the configurations of figures are depicted only for demonstration, not for limitation. Thus, it is known by people skilled in the art that the related elements and layers in a semiconductor structure, the shapes or positional relationship of the elements and the procedure details could be adjusted or changed according to the actual requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1. An electrostatic discharge circuit comprising:
a cascade transistor configuration comprising a first transistor and a second transistor coupled between a power supply node and a ground node; and
a control circuit coupled to the cascade transistor configuration, coupled between the power supply node and the ground node, and comprising:
a voltage drop circuit coupled to the power supply node and the first transistor; and
an electrostatic discharge detecting circuit between the voltage drop circuit and the ground node and coupled to the first transistor and the second transistor, wherein the electrostatic discharge detecting circuit comprises a capacitor, a first resistor, and a second resistor.

2. The electrostatic discharge circuit according to claim 1, wherein the first transistor and the second transistor are all N-type metal-oxide-semiconductor transistors.

3. The electrostatic discharge circuit according to claim 1, wherein the first transistor and the second transistor are arranged in series.

4. The electrostatic discharge circuit according to claim 3, wherein a drain of the first transistor is coupled to the power supply node and a source of the second transistor is coupled to the ground node.

5. The electrostatic discharge circuit according to claim 1, wherein body regions of the first transistor and the second transistor are all coupled to the ground node.

6. The electrostatic discharge circuit according to claim 1, wherein the voltage drop circuit comprises at least one diode.

7. The electrostatic discharge circuit according to claim 1, wherein the voltage drop circuit comprises a plurality of diodes arranged in series.

8. The electrostatic discharge circuit according to claim 1, wherein the voltage drop circuit is coupled to a gate of the first transistor with a first node.

9. (canceled)

10. The electrostatic discharge circuit according to claim 1, wherein the capacitor, the first resistor and the second resistor are arranged in series and coupled between the first node and the ground node.

11. The electrostatic discharge circuit according to claim 1, wherein a dropped voltage in response to a voltage dropped by the voltage drop circuit is less than a breakdown voltage of the first transistor.

12. The electrostatic discharge circuit according to claim 1, wherein a second node between the first resistor and the second resistor is coupled to a gate of the second transistor.

13. The electrostatic discharge circuit according to claim 12, wherein the first resistor and the second resistor generate a divided voltage at the second node.

14. The electrostatic discharge circuit according to claim 1, wherein the first resistor has a first electrical resistance, the second resistor has a second electrical resistance, the first electrical resistance is larger than the second electrical resistance.

15. The electrostatic discharge circuit according to claim 1, wherein the first resistor has a first electrical resistance, the second resistor has a second electrical resistance, a ratio of the first electrical resistance to the second electrical resistance ranges substantially from 1 to 2.

16. The electrostatic discharge circuit according to claim 15, wherein the first electrical resistance and the second electrical resistance are all larger than 5 Kohm.
